(19) United States
(12) Patent Application Publication
(10) Pub. No.: US 2014/0352771 A1
(43) Pub. Date: Dec. 4, 2014

(54) METHOD FOR MANUFACTURING BOWL-SHAPED SURFACE STRUCTURES OF SINGLE-CRYSTALLINE SILICON SUBSTRATES AND A SINGLE-CRYSTALLINE SILICON SUBSTRATE WITH BOWL-SHAPED SURFACE STRUCTURES

(71) Applicant: NATIONAL CENTRAL UNIVERSITY, Jhongli City (TW)

(72) Inventors: Shao-Liang CHENG, Jhongli City (TW); Cheng-Hsuan CHUNG, Jhongli City (TW)

(21) Appl. No.: 13/937,882

(22) Filed: Jul. 9, 2013

(30) Foreign Application Priority Data
May 28, 2013 (TW) 102118843

(51) Int. Cl. H01L 31/0236; H01L 31/18

(52) U.S. Cl. CPC H01L 31/02363; H01L 31/1804
USPC 136/256; 438/71; 257/618

(57) ABSTRACT

A single-crystalline silicon substrate with bowl-shaped surface structures and a manufacturing method of the same are provided. The manufacturing method comprises a sandblasting treatment for forming a textured structure on one surface of the single-crystalline silicon substrate and an etching process for etching the textured structure into plural bowl-shaped surface structures, thereby to manufacture the bowl-shaped surface structures with anti-reflection effect and to lower the reflection ratio of the single-crystalline silicon substrate. Without the need of coating an anti-reflection film, the single-crystalline silicon substrate with bowl-shaped textured surface structures has a very low reflection ratio of less than 2% in the 400-800 nm wavelength visible light region, and can be used as efficient silicon-based solar cell substrate.

### BACKGROUND OF THE INVENTION

1. Technical Field

The present invention relates to methods for manufacturing textured surface structures of single-crystalline silicon substrates and single-crystalline silicon substrates manufactured by the methods, and more particularly, to a method for manufacturing bowl-shaped surface structures of single-crystalline silicon substrates and a single-crystalline silicon substrate with bowl-shaped surface structures.

2. Description of Related Art

Among a wide variety of conventional solar cell substrates, single-crystalline silicon substrates feature high stability and high heat resistance and thus are widely applicable and popular. However, despite years of R&D and improvement, conventional solar cell-oriented single-crystalline silicon substrates has a high reflection ratio of 10% to 20% in visible light region (with wavelength of 400-800 nm approximately).

To solve the aforesaid problem, the prior art discloses plating an anti-reflection film to a light-incident surface of a single-crystalline silicon substrate with a reflection ratio of 10% to 20% with a view to reducing the reflection ratio of the single-crystalline silicon substrate toward light of visible light wavelength. However, the step of plating an anti-reflection film not only requires controlling thickness by a precise process but also takes much time and incurs additional costs on instruments and materials.

Accordingly, it is imperative to provide a single-crystalline silicon substrate which is manufactured easily and capable of cutting spending and features ease of use and satisfactory anti-reflection rate and a method for manufacturing the same, such that the single-crystalline silicon substrate thus manufactured not only meets manufacturers' need for wide application but also appeals to the majority of users and serves as a green energy source conducive to saving energy and reducing carbon emission and thereby fit for large-scale promotion.

### SUMMARY OF THE INVENTION

The present invention relates to a method for manufacturing bowl-shaped surface structures of single-crystalline substrates and a single-crystalline silicon substrate with bowl-shaped surface structures. The manufacturing method entails performing a sandblasting treatment and chemical solution etching to manufacture anti-reflection textured surface structures on the surfaces of the single-crystalline silicon substrate quickly and easily at a low cost and thus effectively reduce the reflection ratio of the single-crystalline silicon substrate toward light. Hence, the method achieves very low reflection, dispenses with the need to plate an anti-reflection film, and reduces the average reflection ratio of the single-crystalline silicon substrates in the 400-800 nm wavelength visible light region to less than 2%, thereby allowing the single-crystalline silicon substrates to be applicable to the manufacturing of high-efficiency silicon-based solar cells.

The present invention provides a method for manufacturing bowl-shaped surface structures of single-crystalline silicon substrates. The method comprises the steps of: providing a single-crystalline silicon substrate, wherein the single-crystalline silicon substrate is fixed separably to a baseboard made of a rigid material; performing a sandblasting treatment on the single-crystalline silicon substrate to thereby sandblast the single-crystalline silicon substrate, such that the single-crystalline silicon substrate has a textured surface full of a plurality of textured surface structures; performing first-instance rinsing for removing the single-crystalline silicon substrate having the textured surface from the baseboard and performing ultrasonic rinsing on the single-crystalline silicon substrate to remove therefrom residual impurities left behind by the sandblasting step; forming bowl-shaped surface structures by etching the textured surface with an etching solution until each textured surface structure forms a bowl-shaped surface structure; and performing second-instance rinsing by performing ultrasonic rinsing on the single-crystalline silicon substrate having the bowl-shaped surface structures and removing the residual etching solution from a surface of the single-crystalline silicon substrate.

The present invention further provides a single-crystalline silicon substrate with bowl-shaped surface structures manufactured by the aforesaid method, such that the single-crystalline silicon substrate has a textured surface, and the textured surface is full of a plurality of bowl-shaped surface structures.

Implementation of the present invention at least involves the following inventive steps:

1. manufacturing single-crystalline silicon substrates of a low reflection ratio quickly and easily at a low cost;

2. dispensing with the need to plate an anti-reflection film on light-incident surfaces of the single-crystalline silicon substrates; and

3. reducing the average reflection ratio of single-crystalline silicon substrates toward light which falls into 400-800 nm wavelength visible light region to less than 2% so that the single-crystalline silicon substrates can be applied to the manufacturing of high-efficiency silicon-based solar cells.

The features and advantages of the present invention are detailed hereinafter with reference to the preferred embodiments. The detailed description is intended to enable a person skilled in the art to gain insight into the technical contents disclosed herein and implement the present invention accordingly. In particular, a person skilled in the art can easily understand the objects and advantages of the present invention by referring to the disclosure of the specification, the claims, and the accompanying drawings.

### BRIEF DESCRIPTION OF THE DRAWINGS

The invention as well as a preferred mode of use, further objectives and advantages thereof will be best understood by reference to the following detailed description of illustrative embodiments when read in conjunction with the accompanying drawings, wherein:

FIG. 1 is a flow chart of a method for manufacturing single-crystalline silicon substrates with bowl-shaped surface structures according to an embodiment of the present invention;

FIG. 2 is a top view of a single-crystalline silicon substrate fixed to a baseboard according to an embodiment of the present invention;

FIG. 3 is a schematic cross-sectional view of a sandblasting treatment performed on the single-crystalline silicon substrate according to an embodiment of the present invention;

FIG. 4 is a schematic cross-sectional view of a single-crystalline silicon substrate which has undergone a sandblasting treatment and has a textured surface full of a plurality of textured surface structures according to an embodiment of the present invention;

FIG. 5 is a schematic view of etching a textured surface of the single-crystalline silicon substrate with an etching solution according to an embodiment of the present invention; and

FIG. 6 is a cross-sectional view of a single-crystalline silicon substrate with bowl-shaped surface structures according to an embodiment of the present invention.

### DETAILED DESCRIPTION OF THE EMBODIMENTS OF THE INVENTION

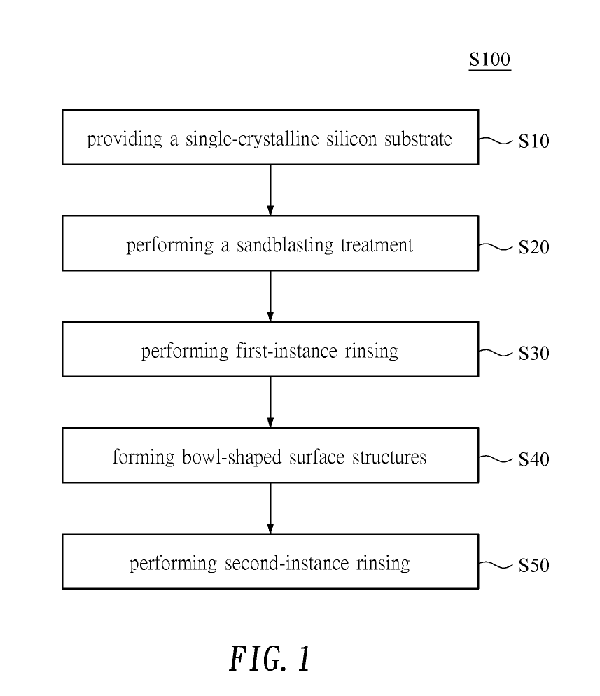

Referring to FIG. 1, a method S100 for manufacturing bowl-shaped surface structures of singe-crystalline silicon substrates comprises the steps of: providing a single-crystalline silicon substrate (step S10), performing a sandblasting treatment (step S20), performing first-instance rinsing (step S30), forming bowl-shaped surface structures (step S40), and performing second-instance rinsing (step S50).

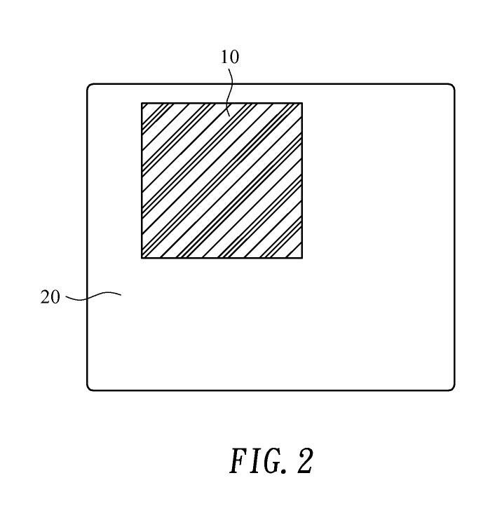

Referring to FIG. 1 and FIG. 2, in the step of providing a single-crystalline silicon substrate (step S10), a single-crystalline silicon substrate 10 is fixed separably to a baseboard 20 made of a rigid material, such as steel, wherein the baseboard 20 carries the single-crystalline silicon substrate 10 and wards off the sand that falls outside the single-crystalline silicon substrate 10 while a sandblasting treatment (step S20) is taking place.

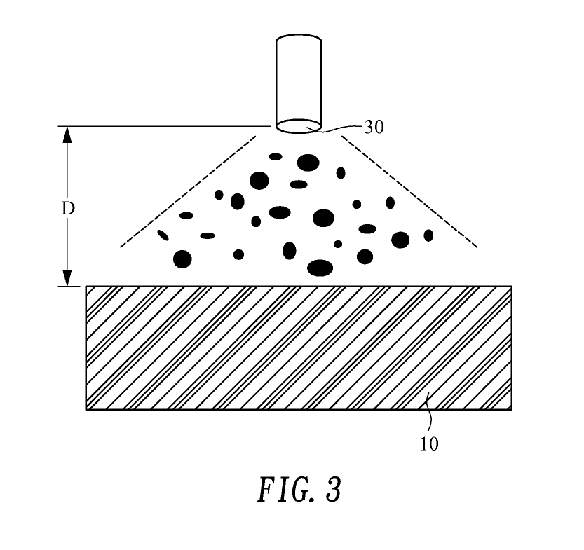

Referring to FIG. 1 and FIG. 3, in the step of performing a sandblasting treatment (step S20), a surface of the single-crystalline silicon substrate 10 is sandblasted by means of a sandblaster operating at a selectively constant sandblasting speed with a constant distance D between a sandblasting nozzle 30 of the sandblaster and a surface (i.e., light-incident surface) of the single-crystalline silicon substrate 10, such that not only can step S20 be performed repeatedly, but the magnitude of the sandblasting force of the sandblaster can also be controlled in a manner to avoid cracking the single-crystalline silicon substrate 10.

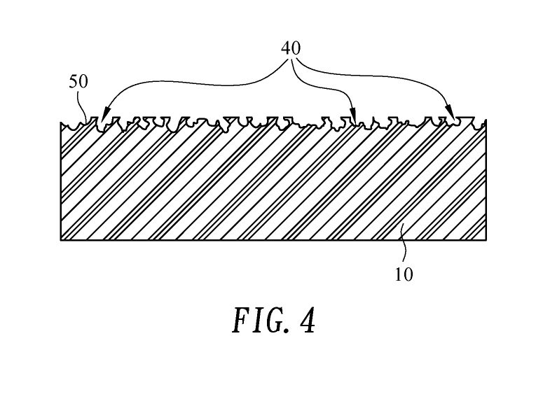

Referring to FIG. 4, after undergoing step S20, the single-crystalline silicon substrate 10 has a textured surface 50 full of a plurality of textured surface structures 40. The textured surface structures 40 not only feature irregular distribution but are also inconsistent in size.

Referring to FIG. 1, after step S20, it is necessary to perform first-instance rinsing (step S30) by removing the single-crystalline silicon substrate 10 having the textured surface 50 from the baseboard and performing ultrasonic rinsing on the single-crystalline silicon substrate 10.

The single-crystalline silicon substrate 10 not only forms the textured surface 50 full of a plurality of textured surface structures 40, but also retains a trace of residual sand on the single-crystalline silicon substrate 10 and/or the textured surface 50. Hence, it is necessary to remove the sand by step S30. Step S30 entails removing the single-crystalline silicon substrate 10 having the textured surface 50 from a baseboard (not shown) and then performing ultrasonic rinsing on the single-crystalline silicon substrate 10. For example, ultrasonic rinsing is performed with acetone, and then ultrasonic rinsing is performed with deionized water (DI water), so as to remove residual sand.

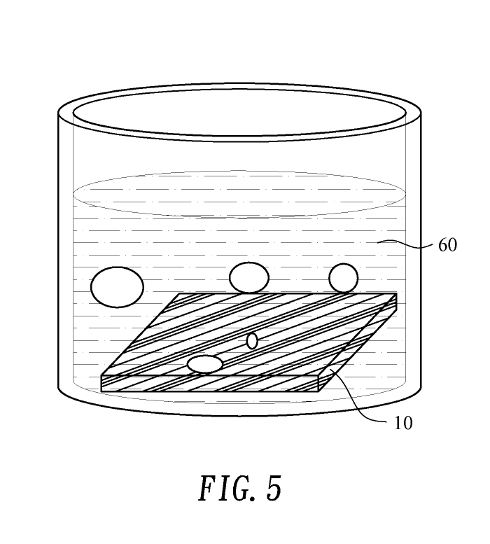

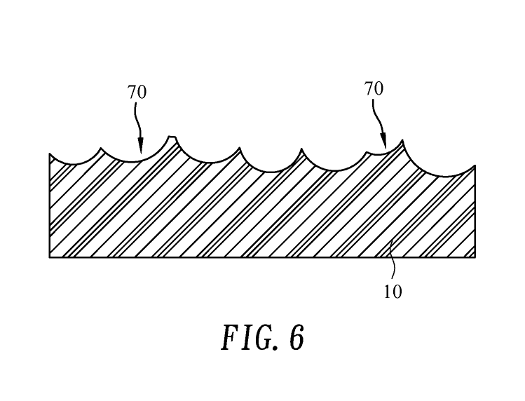

Referring to FIG. 1, FIG. 5 and FIG. 6, the method further entails performing the step of forming bowl-shaped surface structures (step S40), wherein the textured surface 50 of the single-crystalline silicon substrate 10 is etched with an etching solution 60 until each textured surface structure 40 forms a bowl-shaped surface structure 70. In this embodiment, the etching solution 60 is an aqueous solution of hydrofluoric acid (HF), nitric acid (HNO₃) and water (H₂O) mixed in a ratio of 5:1:5.

Referring to FIG. 1, FIG. 5 and FIG. 6, in this embodiment, the etching process whereby the bowl-shaped surface structures are formed (step S40) is a wet etching process, and the etching duration can be adjusted in accordance with the result of the sandblasting treatment until each textured surface structure 40 forms a bowl-shaped surface structure 70. In this embodiment, the etching duration is 10-15 minutes.

Referring to FIG. 1 and FIG. 6, the bowl-shaped surface structures 70 formed on the single-crystalline silicon substrate 10 in step S40 are microscale bowl-shaped surface structures 70.

Referring to FIG. 1 and FIG. 6, the method further entails performing second-instance rinsing (step S50). After step S40, a trace of the residual etching solution is found on the single-crystalline silicon substrate 10 and the bowl-shaped surface structures 70, and thus it is necessary to perform step S50 in order to perform ultrasonic rinsing on the single-crystalline silicon substrate 10 having the bowl-shaped surface structures 70, for example, performing ultrasonic rinsing with acetone, and then performing ultrasonic rinsing with deionized water, so as to remove the residual etching solution 60.

Referring to FIG. 6, there is shown a cross-sectional view of the single-crystalline silicon substrate 10 with the bowl-shaped surface structures 70 manufactured by the method S100, wherein a surface (i.e., the light-incident surface of solar cell substrates) of the single-crystalline silicon substrate 10 is full of a plurality of bowl-shaped surface structures 70. The single-crystalline silicon substrate 10 with the bowl-shaped surface structures 70 has a reflection ratio of less than 2% toward light that falls into 400-800 nm wavelength visible light region so as to function as a satisfactory silicon-based solar cell substrate and enhance photoelectric conversion efficiency of silicon-based solar cells.

The single-crystalline silicon substrate with bowl-shaped surface structures has a low reflection ratio for two reasons as follows: first, the bowl-shaped surface structures cause incident light to undergo multiple scattering, thereby enhancing its light trapping effect; second, the bowl-shaped surface structures provide a graded-refractive index between air and the surface of the silicon crystalline substrate, that is, forming surface structures of a graded-refractive index to thereby inhibit reflection of visible light effectively.

The embodiments described above are intended only to demonstrate the technical concept and features of the present invention so as to enable a person skilled in the art to understand and implement the contents disclosed herein. It is understood that the disclosed embodiments are not to limit the scope of the present invention. Therefore, all equivalent changes or modifications based on the concept of the present invention should be encompassed by the appended claims.

1. A method for manufacturing bowl-shaped surface structures of single-crystalline silicon substrates, the method comprising the steps of:
providing a single-crystalline silicon substrate, wherein the single-crystalline silicon substrate is fixed separably to a baseboard made of a rigid material;
performing a sandblasting treatment on the single-crystalline silicon substrate to thereby sandblast the single-crystalline silicon substrate, such that the single-crystalline silicon substrate has a textured surface full of a plurality of textured surface structures;
performing first-instance rinsing for removing the single-crystalline silicon substrate having the textured surface from the baseboard and performing ultrasonic rinsing on the single-crystalline silicon substrate to remove therefrom residual impurities left behind by the sandblasting step;
forming bowl-shaped surface structures by etching the textured surface with an etching solution until each textured surface structure forms a bowl-shaped surface structure; and
performing second-instance rinsing by performing ultrasonic rinsing on the single-crystalline silicon substrate having the bowl-shaped surface structures and removing the residual etching solution from a surface of the single-crystalline silicon substrate.

2. The method of claim 1, wherein the sandblasting treatment is performed by means of a sandblaster at a constant sandblasting speed and with a constant distance between a sandblasting nozzle of the sandblaster and the single-crystalline silicon substrate.

3. The method of claim 1, wherein the first-instance rinsing entails performing ultrasonic rinsing with acetone and then performing ultrasonic rinsing with deionized water.

4. The method of claim 1, wherein the second-instance rinsing entails performing ultrasonic rinsing with acetone and then performing ultrasonic rinsing with deionized water.

5. The method of claim 1, wherein the etching solution is an aqueous solution of hydrofluoric acid, nitric acid and water which are mixed in a ratio of 5:1:5.

6. The method of claim 1, wherein the bowl-shaped surface structures are microscale bowl-shaped surface structures.

7. A single-crystalline silicon substrate with bowl-shaped surface structures manufactured by the method of claim 1.

8. The single-crystalline silicon substrate of claim 7, wherein the bowl-shaped surface structures are microscale bowl-shaped surface structures.

9. The single-crystalline silicon substrate of claim 7, which has a reflection ratio of less than 2% in 400-800 nm wavelength visible light region.

10. The single-crystalline silicon substrate of claim 7, which is a silicon-based solar cell substrate.
